(19) United States
(12) Patent Application Publication
(10) Pub. No.: US 2016/0064584 A1
(43) Pub. Date: Mar. 3, 2016

(54) SOLAR MODULE REAR SIDE ENCAPSULATION ELEMENT AND SOLAR MODULE

(71) Applicant: HANWHA Q CELLS GMBH, Bitterfeld-Wolfen (DE)

(72) Inventors: Maximilian SCHURADE, Sandersdorf (DE); Markus TRÄGER, Leipzig (DE); Michael METTE, Bitterfeld (DE)

(21) Appl. No.: 14/839,435

(22) Filed: Aug. 28, 2015

(30) Foreign Application Priority Data
Sep. 3, 2014 (DE) 102014112650.5

(51) Int. Cl. H01L 31/048; B32B 27/32; B32B 27/36; B32B 5/02; B32B 27/12

(52) U.S. Cl. CPC H01L 31/048; B32B 5/028; B32B 27/12; B32B 27/36; B32B 27/32; B32B 2457/12; B32B 2262/103

(57) ABSTRACT

A solar module rear side encapsulation element having a laminate-type layer construction having at least one polymer plate or polymer foil having a laminate surface. The laminate-type layer construction has at least one protective layer having layer openings. The protective layer covers at least 70% of the laminate surface by a covering area, and due to the layer openings at least 15% and maximum 99.9% of the regions of the solar module rear side encapsulation element lying under the protective layer are covered in the covering area, and the protective layer is formed as a structure made of threads, thus being open to diffusion.

### PRIORITY CLAIM

The present application claims priority to German Patent Application No. 102014112650.5, filed on Sep. 3, 2014, which said application is incorporated by reference in its entirety herein.

### FIELD OF THE INVENTION

The present invention relates a solar module rear side encapsulation element and a solar module comprising this solar module rear side encapsulation element.

### BACKGROUND OF THE INVENTION

A solar module rear side encapsulation element should be so weather resistant that a sufficient isolation of the solar cells of the solar module to weather exists even after decades in outdoor use. Generally, this is ensured by laminates made of polyvinyl fluoride (PVF) (e.g., Tedlar®, DuPont, USA, Wilmington) and polyethylene terephthalate (PET), polyethylene terephthalate being generally arranged as an isolating central film between two Tedlar® films and optionally further adhesive layers. Also, layers made of polyolefins, polyamide or other polymers can be used. For example, such a laminate-type construction of a solar module rear side encapsulation element is described in EP2482338A2. This laminate-type layer construction has at least one polymer plate or polymer foil having a laminate plane or surface, respectively. According to the invention a polymer plate is thicker and harder or stiffer compared to a polymer foil. Polymer plates and polymer foils can be made of the same material or of different materials. For example, polyester polymer plates or polymer foils, polyolefin polymer plates or polymer foils, fluorine containing polymer plates or polymer foils can be used as polymer plates or polymer foils, respectively. Examples for materials for a polymer plate or polymer foil, respectively, are polyvinyl fluoride, polyethylene terephthalate and/or polyolefins. Each polymer plate or polymer foil, respectively, can be respectively resistant to UV, mechanically stable and/or adherent. If required, the laminate-type layer construction comprises polymer plates or polymer foils, respectively, as adhesive films. The polymer plates or polymer foils, respectively, can be formed as layer or film, a film being a thin layer in terms of the invention.

A polymer plate or polymer foil is often used in combination with an encapsulation material. The encapsulation materials are in direct contact to the solar cells and are made of ethylene vinyl acetate (EVA), polyvinylbutyral (PVB), as ionomers, polyolefins or silicones, for example. The same or different encapsulation materials can be used in front of or behind the solar cells, when viewed from the direction of sunlight incidence.

Since Tedlar® and also other fluorine polymers are comparatively costly and hard to recycle, a special polyester foil is proposed as a solar module rear side encapsulation element in EP2482338A2. Although it has an improved resistance to hydrolysis and good electro-isolating properties, it is not able to protect a solar module sufficiently long in a weather-resistant manner in regions having many dust storms and sandstorms and increased UV exposure. Thus, such a solar module is of limited suitability for use in a desert region.

Especially in desert regions where solar modules are exposed to increased mechanical stress by sandstorms and increased UV exposure the wear of current solar modules is higher. This is due to the fact that the polymer foils used are of limited resistance to UV radiation and in view of a required service life of up to twenty years have too low mechanical stability with respect to abrasion.

### SUMMARY OF THE INVENTION

It is an object of the invention to provide a solar module rear side encapsulation material and a solar module which are sufficiently weather-resistant during increased UV exposure and mechanical abrasive stress in particular by sand and dust.

This object is solved by a solar module rear side encapsulation element having the features of the claims described herein.

According to an embodiment of the invention, the laminate-type layer construction has at least one protective layer having layer openings, the protective layer covering at least 70% of the laminate surface by a covering area. Due to the layer openings of the protective layer at least 15% and maximum 99.9% of the regions of the solar module rear side encapsulation element lying under the protective layer are covered in the covering area. The layer openings in the protective layer are arranged in such a manner that the protective layer forms a structure made of threads being open to diffusion. The structure made of threads is realized by a regular thread system in particular a woven or knitted fabric and/or by an irregular thread system in particular a non-crimped fabric.

The protective layer serves to protect the subjacent polymer components of the laminate-type layer construction of the rear side encapsulation element against mechanical abrasion especially by sand and to protect these polymeric components to degradation by UV light. The protective layer prevents or reduces significantly abrasion by sand and protects the subjacent polymer plates or polymer foils to this mechanical damage and to excessive UV radiation. Thus, the solar module rear side encapsulation element offers a better weather-resistance to a solar module in regions having increased UV exposure and dust storms or sandstorms and, thus, it is especially suited for use in a desert region. Furthermore, experiments have shown that solar modules comprising such a rear side encapsulation element having a protective layer made of a thread system incur a significantly higher mechanical stability of the solar module against mechanical stress that is in particular caused by wind or snow.

Furthermore, the solar module rear side encapsulation elements and the solar modules produced using such elements are cost-efficient in view of the advantages achieved by a protective layer formed by a thread system.

Furthermore, the solar module rear side encapsulation element is open to diffusion due to the layer openings in the protective layer, because by the layer openings it is not a planar continuous layer which would be a diffusion barrier. Thus, the protective layer allows a gas diffusing exchange for the laminate-type layer construction with the surroundings. Especially, this is in particular advantageous if the solar module rear side encapsulation element is arranged in a solar module comprising ethylene vinyl acetate as encapsulation material. Acetic acid can be formed by hydrolysis of the ethylene vinyl acetate. If it cannot exhaust from the solar module, this may lead to an undesirable degradation of solar cells and/or electric interconnection structures.

The laminate-type layer construction has at least one protective layer extending along at least 70% of the laminate surface. For this purpose, the protective layer can also comprise segments so that the sum of the protective layer segments cover 70% of the laminate surface. Preferably, the protective layer covers at least 80%, more preferably at least 90%, even more preferably at least 99% of the laminate surface. I.e., edge regions or in case of a segment-like structure, edge regions and intermediate regions can be uncovered by the protective layer.

In regions where the protective layer covers polymeric regions of the laminate-type layer construction, it forms a so-called covering area of the laminate surface. This covering area is a region formed by the sum of the protective layer-polymer-boundary surfaces formed by the protective layer and the at least one polymer plate or polymer foil. This means, in regions of the layer openings of the protective layer such protective layer-polymer-boundary surfaces are lacking due to the layer openings. Thus, in the covering area at least 15% and a maximum 99.9% of the regions of the solar module rear side encapsulation element underlying the protective layer are covered, for example, these areas form horizontally orientated protective layer-polymer-boundary surfaces taking up at least 15% and a maximum 99.9% of the covering area. A covering in the range of from 15% to 20% or 20% to 25% or 25% to 30% can be realized by the formation of the protective layer in the form of a grid. Depending on the relation of the grid bar widths to the grid openings widths, the amount of the covering is larger or smaller. Depending on the design of the layer openings, they are formed rather microscopic or macroscopic, i.e., visible to the naked eye. Preferably, the grid is a woven metal grid.

The laminate-type layer construction may comprise a protective layer having microscopic or macroscopic layer openings visible in top view on the protective layer. For example, the protective layer is a grid of regularly woven metal threads. It is possible in this embodiment to see through the layer openings to the subjacent polymer regions of the laminate-type layer construction.

Furthermore, the protective layer can be formed as a plurality of grids arranged one above the other generally in an irregular manner. Alternatively or additionally, the protective layer can comprise a woven or knitted thread system or a non-crimped fabric like thread system in an irregular loose felt-type structure made of threads. Also, in these embodiments the protective layer has layer openings which, however, generally do not extend in a direction vertical to the surface of the protective layer through the whole protective layer. Rather, they are a plurality of small splits and openings which extend in an irregular distribution in all directions of the spatial structure in the protective layer. In contrast to the grid or metal wire mesh in top view on this protective layer one cannot see through the protective layer to the polymer regions of the laminate-type construction.

The protective layer is formed as a structure made of threads and thus being open to diffusion. A structure being open to diffusion should be understood as a structure which is permeable to fluid such as permeable to acetic acid. The threads can have diameters in the range of from 10 to 500 μm. Preferably, the diameter of the threads is in the range of from 150 to 250 μm. Alternatively, the threads can have diameters larger than 500 μm. The threads can be metal threads, for example, aluminum threads and/or stainless steal threads. Alternatively or additionally, the threads can be glass fiber threads and/or carbon fiber threads. In a preferred embodiment the threads are metal threads or metal containing threads. Especially due to cost reasons, aluminum threads are preferred. Even twisted variations of metal threads, glass fiber threads and/or carbon fiber threads can be used in the form of regular thread systems (in particular woven fabrics and knitted fabrics) or irregular thread systems (in particular felt-type non-crimped fabrics).

In a preferred embodiment the protective layer has a surface structure with a surface structure area, the surface structure area being at least 10% larger than the covering area of the laminate surface. More preferably, the surface structure area is at least twice as large as the covering region of the laminate surface. For example, the protective layer made of metal can have metal protrusions extending from the metal layer plane in the direction opposite to the laminate-type layer construction. When the surface structure area of the protective layer is larger than the covering region of the laminate surface, a positive effect with respect to the solar module temperature is achieved due to a better heat conduction and heat distribution. Thereby, heat dissipation of the solar module is enhanced due to the increased surface.

In a preferred embodiment on the protective layer one or more polymer foils and/or polymer layers and/or a sacrificial layer made of a non-polymeric and non-metallic material are applied. For example, the protective layer is arranged between the polymer foils or polymer layers or polymer plates, respectively, or between the sacrificial layer and the at least one subjacent polymer plate or polymer foil in a sandwich-like manner. The upper polymer layers or the sacrificial layer protect the protective layer to undesired damages, for example, during mounting. Then, during the subsequent field use the mechanical abrasion would first remove the polymer layers arranged on the protective layer or the sacrificial layer by degrees. However, as soon as the protective layer is reached, the abrasion rate is slowed due to the increased mechanical resistance of the protective layer.

Preferably, the laminate-type layer construction comprises no polyvinyl fluoride plate or polyvinyl fluoride polymer foil, respectively. In a preferred embodiment a material of the at least one polymer plate or polymer foil is polyethylene terephthalate and/or a polyolefin. Thereby, a solar module provided with this embodiment of the solar module rear side encapsulation element is especially cost-efficient.

Preferably, a laminate-type layer construction has three layers, a layer made of polyethylene terephthalate being arranged between an adhesion layer made of polyethylene in direction to the embedding material and the protective layer. Advantageously, the laminate-type layer construction can have further adhesive films and/or bonding films. An especially simple variation of the laminate-type layer construction has as polymer plate or foil only one polymer film as embedding material for solar cell strings that is covered by the protective layer. The protective layer especially in the form of a metal protective layer is embedded into the polymer plate or foil by a melting process. Alternatively, an adhesive film can be arranged between the polymer plate or foil and the protective layer.

In an alternatively preferred embodiment the protective layer is arranged on a bonding film arranged on an adhesive film. Preferably, the solar module rear side encapsulation element is constructed as follows: protective layer/adhesive film/core film, e.g., made of polyethylene terephtalate/adhesive film/bonding film for solar cell strings made of polyolefin such as polyethylene. Alternatively, polyvinyl fluoride can also be arranged in the layer construction described above instead of the polyolefin. The polyolefin variation is more cost-efficient than the polyvinyl fluoride variation. However, it is more resistant to UV radiation. Also, other connecting means and methods such as ultrasonic welding can be used instead of the adhesive film.

Furthermore, the invention relates to a solar module comprising a front side and a rear side, solar cell strings being arranged on the rear side of the front side encapsulation element and being electrically connected to each other, and a solar module rear side encapsulation element according to one of the preceding embodiments. Such a solar module has long-term weather-resistance and is cost-efficient. Especially, it has a high resistance to abrasion by sand and to degradation by UV radiation.

For example, the front side encapsulation element comprises a glass plate and/or a polymer plate or foil. Preferably, the front side encapsulation element is formed as a glass plate. The solar cell strings are arranged on the rear side of the glass plate and are connected to each other. The solar module rear side encapsulation element has the laminate-type layer construction as described above with at least one polymer plate or polymer foil and the protective layer having layer openings. Preferably, the protective layer is a metal protective layer.

Preferably, the at least one polymer plate or polymer foil comprises an encapsulation material for the solar cell strings of the solar module so that the protective layer is located on the side of the layer construction facing away from the encapsulation material. The protective layer can be the outer face of the solar module. Alternatively, further polymer foils and/or polymer layers or a sacrificial layer made of non-polymeric and non-metallic material are applied on the protective layer

In a preferred embodiment the solar module comprises a metallic frame construction and the protective layer especially in the form of a metal protective layer and the metallic frame construction can be contacted electrically to each other. Especially, this is necessary, when it is required by law in the respective field of use. For example, the protective layer especially the metal protective layer can be connected electrically to the metallic frame construction during framing the solar module, for example, in a frame groove provided or screwed together with the frame. However, the protective layer can also be applied subsequently after framing the solar module, thus, for upgrading of an already produced solar module. Then, it is possible to provide grounding of the at least one protective layer by electrically conductive elements that are provided for this purpose in the form of a conductive tape.

Alternatively, it is possible that the at least one protective layer especially the metal protective layer is electrically isolated from the frame. Then, the at least one protective layer can be used to create a defined electrical opposing field. It can make a contribution for monitoring and/or electrically protecting solar modules or even prevent voltage peaks during thunderstorm situations.

In a preferred embodiment the protective layer of the solar module rear side encapsulation element is laminated into the rear side encapsulation element or embedded into the rear side encapsulation element. In this case further polymer foils and/or polymer layers which can serve to protect the protective layer are applied on the protective layer. In this case the protective layer is arranged between the polymer foils in sandwich-like manner.

Furthermore, it is possible to thermally connect the at least one protective layer especially the metal protective layer to a junction box of the solar module. In this manner the heat developing generally in the semiconductor diodes provided in the junction boxes can be dissipated and distributed in a better manner via the back surface of the solar module. Also, it is possible to integrate in the solar module rear side encapsulation element electrically conductive elements serving to contact and connect the solar cells of the solar module.

Alternatively it is preferred that the protective layer forms the outermost layer of the solar module rear side encapsulation element. Thereby, the solar module rear side encapsulation element or the solar module is more cost-efficient compared to the embodiment above in which the protective layer is laminated.

### BRIEF DESCRIPTION OF THE FIGURES

In the following, the invention is explained by several embodiments with reference to the Figures. Here, the Figures show schematically:

FIG. 1 a schematic and non-scaled partial cross-sectional view of a solar module having a solar module rear side encapsulation element according to a first embodiment;

FIG. 2 a schematic and non-scaled partial cross-sectional view of a solar module rear side encapsulation element according to a second embodiment;

FIG. 3 a schematic and non-scaled partial cross-sectional view of a solar module rear side encapsulation element according to a third embodiment;

FIG. 4 a schematic and non-scaled partial cross-sectional view of a solar module rear side encapsulation element according to a fourth embodiment;

FIG. 5 a schematic and non-scaled partial cross-sectional view of a solar module rear side encapsulation element according to a fifth embodiment; and

FIG. 6 a schematic and non-scaled partial cross-sectional view of a solar module rear side encapsulation element according to a sixth embodiment.

### DETAILED DESCRIPTION

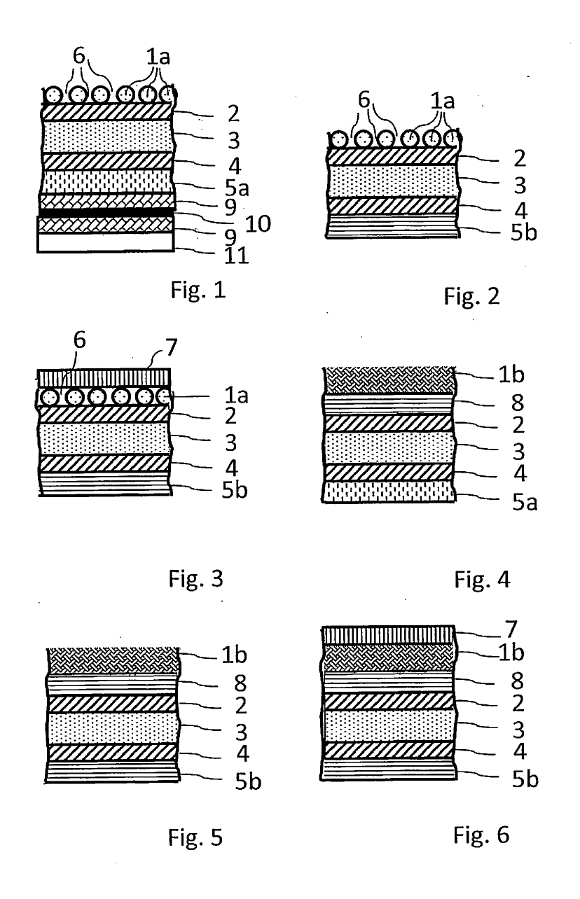

FIG. 1 shows a schematic and non-scaled partial cross-sectional view of a solar module having a solar module rear side encapsulation element according to a first embodiment. The solar module has a front side encapsulation element 11, the front side thereof being a light-incident side of the solar module and an encapsulation material 9 being arranged on the rear side thereof. Furthermore, the solar module comprises solar cell strings 10 arranged on the rear side of the front side encapsulation element 11 that are connected to each other and embedded in the encapsulation material 9 so that both the side of the solar cell string 10 facing to the front side encapsulation element 11 and the side of the solar cell string 10 facing away from the front side encapsulation element 11 are surrounded by the encapsulation material 9. Furthermore, the solar module has a solar module rear side encapsulation element arranged on the side of the solar cell string 10 facing away from the front side encapsulation element 11 and the encapsulation material 9, respectively, which can be also part of the rear side encapsulation element. The solar module rear side encapsulation element comprises a protective layer 1a, an adhesive film 2, a polyethylene terephthalate layer 3, an adhesive film 4, and a polyvinyl fluoride film 5a. The protective layer 1a in the form of a plurality of metal threads has a plurality of layer openings 6 and is formed, for example, as a grid in form of a woven fabric of metal threads. The sectional view shown in FIG. 1 cuts a plurality of equally spaced-apart warp threads of the woven fabric of metal threads. The protective layer 1a has layer openings 6 visible in top view on the protective layer 1a. The protective layer 1a covers in vertical view on the laminate at least 90% of the laminate surface which is not shown completely here, and thereby, occupies a covering area on the laminate surface. Due to the layer openings 6 the protective layer 1a covers depending on the embodiment in the covering area at least 15% and maximum 99.9% of the polymer regions of the solar module rear side encapsulation element especially the adhesive film 2 lying under the protective layer 1a. The adhesive films 2 and 4 may be made of identical or different materials. The solar module rear side encapsulation element is arranged in a solar module (not completely shown) in such a manner that the polyvinyl fluoride film 5a is arranged on an encapsulation material such as ethylene vinyl acetate The protective layer 1a forms the outer face of the rear side of the solar module that is not shown completely in FIG. 1.

In the following FIGS. 2 to 6 and non-scaled partial cross-sectional views of further embodiments of further solar module rear side encapsulation elements are shown schematically. The respective rear side encapsulation element is shown and described by polyvinyl fluoride films 5a or polyolefin films 5b, respectively, arranged as shown and described in FIG. 1 in a solar module having a front side encapsulation element, encapsulation material and solar cell string. However, for the sake of clarity in FIGS. 2 to 6 respectively only the rear side encapsulation element of the solar module is shown.

FIG. 2 shows a schematic and non-scaled partial cross-sectional view of a solar module rear side encapsulation element according to a second embodiment. The solar module rear side encapsulation element shown in FIG. 2 corresponds to the solar module rear side encapsulation element shown in FIG. 1 with the difference that it comprises a more cost-efficient polyolefin film 5b made of polyethylene instead of the polyvinyl fluoride film 5a.

FIG. 3 shows a schematic and non-scaled partial cross-sectional view of a solar module rear side encapsulation element according to a third embodiment. The solar module rear side encapsulation element shown in FIG. 3 corresponds to the solar module rear side encapsulation element shown in FIG. 2 with the difference that the protective layer 1a is laminated. A polymer foil 7 is arranged on the protective layer 1a so that the polymer foil 7 is the outer face of the rear side encapsulation element and the solar module not shown completely. Alternatively, the outermost layer can be also formed as sacrificial layer made of a non-polymeric and non-metallic material.

FIG. 4 shows a schematic and non-scaled partial cross-sectional view of a solar module rear side encapsulation element according to a fourth embodiment. The solar module rear side encapsulation element shown in FIG. 4 corresponds to the solar module rear side encapsulation element shown in FIG. 1 with the difference that instead of the protective layer 1a in form of a grid as a woven fabric it comprises a protective layer 1b made of a plurality of metal threads arranged irregularly and that a polyolefin film 8 as adhesive film is arranged between the adhesive film 2 and the protective layer 1b. The protective layer 1b forms a protective layer in the same way as in the preceding embodiments. this protective layer is being open to diffusion due to its structure made of metal threads having a plurality of small layer openings randomly distributed in a three dimensional structure that is not shown in detail here. The protective layer 1b has layer openings which do not extend vertically to the surface of the protective layer 1b penetrating in a straight orientation the whole protective layer 1b. Rather, they form a plurality of small splits and openings which extend in an irregular distribution in all directions of the spatial structure in the protective layer 1b. In contrast to the embodiment shown in FIG. 1 in a macroscopic top view on the protective layer 1b one cannot see through the protective layer 1b to the polymer regions of the laminate-type construction.

FIG. 5 shows a schematic and non-scaled partial cross-sectional view of a solar module rear side encapsulation element according to a fifth embodiment. The solar module rear side encapsulation element shown in FIG. 5 corresponds to the solar module rear side encapsulation element shown in FIG. 4 with the difference that it comprises a polyolefin film 5b made of polyethylene instead of the polyvinyl fluoride film 5a.

FIG. 6 shows a schematic and non-scaled partial cross-sectional view of a solar module rear side encapsulation element according to a sixth embodiment. The solar module rear side encapsulation element shown in FIG. 6 corresponds to the solar module rear side encapsulation element shown in FIG. 5 with the difference that a polymer foil 7 is arranged on the protective layer 1a so that the polymer foil 7 is the outer face of the rear side encapsulation element and the solar module not shown completely.

List of reference numbers:

| 1a | protective layer in the form of a regular metal thread system |
|---|---|
| 1b | protective layer in the form of an irregular metal thread system |
| 2 | adhesive film |
| 3 | polyethylene terephthalate layer |
| 4 | adhesive film |
| 5a | polyvinyl fluoride film |
| 5b | polyolefin film |
| 6 | layer opening |
| 7 | polymer foil |
| 8 | polyolefin film |
| 9 | encapsulation material |
| 10 | solar cell string |
| 11 | front side element |

1. A solar module rear side encapsulation element comprising:
a laminate-type layer construction having at least one polymer plate or polymer foil having a laminate surface,
wherein
the laminate-type layer construction has at least one protective layer having layer openings, the protective layer covering at least 70% of the laminate surface by a covering area, and
due to the layer openings in the covering area, at least 15% and maximum 99.9% of the regions of the solar module rear side encapsulation element lying under the protective layer are covered, and
the protective layer is formed as a structure made of threads being open to diffusion.

2. The solar module rear side encapsulation element according to claim 1, wherein the threads comprise a plurality of metal threads or metal containing threads.

3. The solar module rear side encapsulation element according to claim 1, wherein the protective layer has a surface structure with a surface structure area, the surface structure area being at least 10% larger than the covering area of the laminate surface.

4. The solar module rear side encapsulation element according to claim 1, wherein on the protective layer, one or more polymer foils and/or polymer layers and/or a sacrificial layer made of a non-polymeric and non-metallic material are applied.

5. The solar module rear side encapsulation element according to claim 1, wherein a material of the plurality of polymer plates and/or polymer foils is polyethylene terephthalate and/or a polyolefin.

6. A solar module comprising:
a front side encapsulation element including a front side and a rear side,
solar cell strings being arranged on the rear side of the front side encapsulation element and being electrically connected to each other,
and a solar module rear side encapsulation element, according to claim 1.

7. The solar module according to claim 6, wherein the solar module rear side encapsulation element comprises an encapsulation material for the solar cell strings.

8. The solar module according to claim 6, wherein the solar module comprises a metallic frame construction, and the protective layer and the metallic frame construction are electrically connected to each other.

9. The solar module according claim 6, wherein the protective layer of the solar module rear side encapsulation element is laminated into the rear side encapsulation element or embedded into the rear side encapsulation element.

10. The solar module according to claim 6, wherein the protective layer forms an outermost layer of the solar module rear side encapsulation element.
